(19) United States
(12) Patent Application Publication
(10) Pub. No.: US 2010/0176369 A2
(43) Pub. Date: Jul. 15, 2010

(54) Metalized Silicon Substrate for Indium Gallium Nitride Light-Emitting Diodes

(76) Inventors: Mark Oliver, Northville, IN (US); Vijay Rawat, San Jose, CA (US); Timothy Sands, West Lafayette, IN (US); Jeremy Schroeder, West Lafayette, IN (US)

Correspondence Address: BOSE MCKINNEY & EVANS LLP, 111 MONUMENT CIRCLE, SUITE 2700, INDIANAPOLIS, IN, 46204, UNITED STATES, 317-684-5414, 317-684-5173, PATENT@BOSELAW.COM

(21) Appl. No.: 12/424,517

(22) Filed: Apr. 15, 2009

Related U.S. Application Data
(60) Provisional application No. 61/051,950, filed on May 9, 2008.
(60) Provisional application No. 61/045,116, filed on Apr. 15, 2008.

(51) Int. Cl. H01L 33/00; H01L 21/20

(52) U.S. Cl. 257/13; 438/46; 257/E33.008; 257/E21.09

(57) ABSTRACT

A light emitting diode having a metallized silicon substrate including a silicon base, a buffer layer disposed on the silicon base, a metal layer disposed on the buffer layer, and light emitting layers disposed on the metal layer. The buffer layer can be AlN, and the metal layer ZrN. The light emitting layers can include GaN and InGaN. The metallized silicon substrate can also include an oxidation prevention layer disposed on the metal layer. The oxidation prevention layer can be AlN. The light emitting diode can be formed using an organometallic vapor phase epitaxy process. The intermediate ZrN/AlN layers enable epitaxial growth of GaN on silicon substrates using conventional organometallic vapor phase epitaxy. The ZrN layer provides an integral back reflector, ohmic contact to n-GaN. The AlN layer provides a reaction barrier, thermally conductive interface layer, and electrical isolation layer.

### CROSS-REFERENCE TO RELATED APPLICATIONS

This application claims the benefit of U.S. Provisional Application Ser. No. 61/045,116, filed on Apr. 15, 2008, entitled “Metallized Silicon Substrate for Indium Gallium Nitride Light-Emitting Diode,” and U.S. Provisional Application Ser. No. 61/051,950, filed on May 9, 2008, entitled “Metallized Silicon Substrate for Indium Gallium Nitride Light-Emitting Diode,” each of which is incorporated herein by reference.

This invention was made in part with support from the Department of Energy with grant number DE-FC26-06NT42862. The Government may have certain rights in the invention.

### BACKGROUND

The present invention relates generally to light emitting diodes, and more particularly to a light emitting diode having a silicon substrate.

Current commercial Gallium Nitride (GaN)-based light emitting devices are almost exclusively fabricated by processes that begin with organometallic vapor phase epitaxy (OMVPE) of aluminum (Al), gallium (Ga) or indium (In) nitride (N), (Al, Ga, In)N, heterostructures on either sapphire or silicon carbide (SiC) substrates. These substrates are suitable for discrete, high-performance laser diode and light-emitting diode devices, despite drawbacks that include poor lattice match (sapphire), light absorption (SiC), low thermal conductivity (sapphire), and difficulty in dicing (sapphire and SiC).

Although some of the detrimental features of sapphire can be mitigated by laser liftoff and transfer of the nitride heterostructures to metallized submounts, this process adds complexity and cost. Sapphire, SiC and more exotic substrates including bulk GaN are also expensive, both on a materials basis and from the perspective of scaling fabrication processes to large diameter wafers (e.g., 300 mm), which are currently unavailable. The initial cost of the substrate and associated constraints of scaling to large die and large wafers limits the ability to develop low-cost, high-performance GaN-based white LEDs for solid-state lighting that can be a replacement for incandescent and fluorescent lighting.

FIG. 1 shows a schematic view of the stacked layers in an exemplary prior art reference, U.S. Pat. No. 6,891,203 to Kozawa et al, for a light emitting element with a sapphire substrate used in a light emitting diode. The layers according to U.S. Pat. No. 6,891,203 include a substrate (sapphire) 11; a buffer layer (AlN) 12; a first n-type layer (n-GaN:Si) 13; a second n-type (n-AlGaN:Si) 14; a light-emitting layer (multiple quantum well structure) 15; a first p-type layer (p-AlGaN:Mg) 16; a second p-type layer (p-AlGaN:Mg) 17; a light-transmitting electrode (Au/Co) 18; a p-electrode 19; and a n-electrode 20.

One possible solution to the substrate problem for solid-state lighting is silicon. Silicon is relatively inexpensive, available in large diameters, easily diced, and thermally conductive. Challenges with silicon include a 20% lattice mismatch with GaN, absorption of visible light, a significant mismatch in the coefficient of thermal expansion with GaN (˜35%), and formation of Si—N during the application of nitrogen in growing GaN or other intermediate layers under conventional growth conditions (T>1000° C.), wherein Si—N substantially prevents further growth of epitaxial crystalline structures.

Therefore, it would be desirable to have a new substrate system to overcome the disadvantages of the above mentioned substrates for cost-effective and scalable manufacturing.

### SUMMARY

One approach to overcoming these disadvantages is through the use of suitable intermediate layers. Embodiments described herein provide a cost-effective alternative substrate for the fabrication of indium gallium nitride-based light emitting diodes, (In,Ga)N LEDs. Compared to current (In,Ga)N LED substrates (i.e., sapphire and silicon carbide), silicon (Si) offers a low cost alternative that is compatible with standard semiconductor fabrication processes and is highly scalable to large diameter substrates.

A zirconium nitride (ZrN) layer is lattice matched to (In,Ga)N, which permits high quality (In,Ga)N growth, and also functions as an integral back contact and reflector for increased LED light output. An intermediate aluminum nitride (AlN) layer provides at least two benefits. First, epitaxial AlN on Si allows epitaxial growth of ZrN, which is not routinely achievable directly on Si. Second, the AlN layer, being chemically stable with both Si and ZrN, acts as a barrier between ZrN and Si, which react at (In,Ga)N deposition temperatures to form zirconium silicide and silicon nitride. The AlN layer provides a chemically robust interface for high temperature growth by a conventional OMVPE system. The AlN also allows electrical isolation of devices fabricated on the same die, as AlN is an electrical insulator. Silicon and aluminum nitride have high thermal conductivities compared to sapphire, the conventional substrate for (In,Ga)N LEDs. The high thermal conductivity of the ZrN/AlN/Si substrate can substantially simplify the packaging of high power LEDs for lighting applications.

One exemplary embodiment includes a light emitting diode having a metallized silicon substrate that includes a silicon base, a buffer layer disposed on the silicon base, a metal layer disposed on the buffer layer, and light emitting layers disposed on the metal layer. The buffer layer can be composed of AlN. The metal layer can be composed of ZrN. The light emitting layers can include an n-type layer disposed on the metal layer, a multiple quantum well structure disposed on the n-type layer, a p-type layer disposed on the multiple quantum well structure, and a transparent layer disposed on the p-type layer. The light emitting diode can also include a p-electrode disposed on the transparent layer. The light emitting diode can also include an n-electrode disposed on the metal layer. The n-type layer can be composed of GaN. The multiple quantum well structure can include GaN and InGaN layers. The p-type layer can be GaN:Mg. The transparent layer can be chosen from the group which includes Au—Ni, Indium Tin Oxide, and ZnO.

Another exemplary embodiment includes a light emitting diode having a metallized silicon substrate that includes a silicon base, a buffer layer disposed on the silicon base, a metal layer disposed on the buffer layer, an oxidation prevention layer disposed on the metal layer; and light emitting layers disposed on the oxidation prevention layer. The light emitting layers can include an n-type layer disposed on the oxidation prevention layer, a multiple quantum well structure disposed on the n-type layer, a p-type layer disposed on the multiple quantum well structure, a transparent layer disposed on the p-type layer, a p-electrode disposed on the transparent layer, and an n-electrode disposed on the metal layer. The buffer layer can be composed of AlN. The metal layer can be composed of ZrN. The oxidation prevention layer can be composed of AlN.

Also disclosed is an exemplary method of forming a light emitting diode having a metallized silicon substrate. The method can include preparing a silicon base surface; depositing a thin layer of aluminum on the silicon base surface; exposing the thin layer of aluminum on the silicon base surface to nitrogen gas to form an aluminum nitride base surface; depositing additional aluminum on the aluminum nitride base surface in the presence of the nitrogen gas to form an aluminum nitride layer; and depositing zirconium on the aluminum nitride layer in the presence of the nitrogen gas to form an zirconium nitride layer. The method can also include depositing gallium nitride film on the zirconium nitride layer using an organometallic vapor phase epitaxy process. The method can also include depositing a thin layer of aluminum in the presence of the nitrogen gas on the zirconium nitride layer to form a thin upper aluminum nitride layer. The thin upper aluminum nitride layer can be about 3 nm in thickness. The method can also include depositing gallium nitride film on the thin upper aluminum nitride layer using an organometallic vapor phase epitaxy process.

### BRIEF DESCRIPTION OF THE DRAWINGS

The above-mentioned aspects of the present invention and the manner of obtaining them will be better understood by reference to the following description of exemplary embodiments, taken in conjunction with the accompanying drawings, wherein:

FIG. 1 is a schematic view of the stacked layers for an exemplary light emitting element shown in the prior art;

FIG. 2 is a schematic view of the stacked layers for an embodiment according to the current teachings;

FIG. 3 is a schematic view of the stacked layers for another embodiment according to the current teachings;

FIG. 4 shows a low magnification annular dark field STEM cross sectional image of a GaN/ZrN/AlN/Si(111) heterostructure;

FIG. 5 shows XRD patterns from the same growth conditions of GaN by OVMPE grown on sapphire and AlN/ZrN/AlN/Si(111); and

FIG. 6 shows asymmetric phi scans showing the epitaxial relationships between the layers.

### DETAILED DESCRIPTION OF EXEMPLARY EMBODIMENTS

The embodiments of the present invention described below are not intended to be exhaustive or to limit the invention to the precise forms disclosed in the following detailed description. Rather, the embodiments are chosen and described so that others skilled in the art may appreciate and understand the principles and practices of the present invention.

It is desirable to have a low-cost substrate that provides an integral back contact and reflector for enhanced performance of indium gallium nitride-based light emitting diodes, (In,Ga)N LEDs. Such a substrate could potentially replace the current substrates of choice, which are sapphire and silicon carbide. A cost effective silicon based substrate can increase device performance, improve scalability, and be compatible with current semiconductor industry fabrication processes.

A substrate having suitable intermediate layers can take advantage of the benefits of a silicon (Si) substrate while overcoming its drawbacks. For example, a metallic layer with high reflectivity can address the absorption problem and simplify the fabrication of an LED by providing both a back reflector and an ohmic contact to n-GaN, A metallic buffer layer between Si and gallium nitride (GaN) may be suitable if it can be grown as an epitaxial film on Si. The metallic layer can also serve as an epitaxial template for GaN, and be sufficiently stable in contact with Si and GaN at temperatures characteristic of OMVPE GaN epitaxy (˜1000° C.) to prevent interfacial reactions. Candidate metallic intermediate layers that have been reported include ZrB₂, TiN, and HfN. Zirconium diboride (ZrB₂) shows promise, but published reports of GaN growth on ZrB₂/Si have been limited to molecular beam epitaxy at 650° C. Titanium nitride (TiN) suffers from a smaller lattice parameter than GaN and cannot be lattice matched to (In,Ga)N. Hafnium nitride (HfN) is also not chemically stable with silicon at high temperatures. No prior reports have been found of GaN growth by OMVPE under conventional growth conditions (T>1000° C.) on metallized silicon substrates.

The refractory metallic phase, zirconium nitride (ZrN), can serve as an intermediate layer between Si and GaN. ZrN has a higher reflectivity in the blue portion of the spectrum than TiN, forms an ohmic contact to n-GaN, and is lattice matched to In_{0.14}Ga_{0.86}N, a suitable buffer layer composition for green LEDs. The principal challenge with ZrN (and HfN) is its reaction with Si, yielding product phases of zirconium silicide (ZrSiₓ) and silicon nitride (Si₃N₄).

An intermediate aluminum nitride (AlN) buffer layer can prevent the reaction between ZrN and Si, and facilitate epitaxy in GaN/ZrN/AlN/Si(111) heterostructures, yielding epitaxial GaN overlayers with 0002 omega rocking curve full-width-at-half-maximum (FWHM) values as low as 1230 arc sec for a GaN film of 800 nm thickness. The AlN buffer layer also provides a thermally conductive but electrically insulating layer that permits the electrical isolation of devices on the same die, a distinct advantage when designing integrated multi-wavelength emitters.

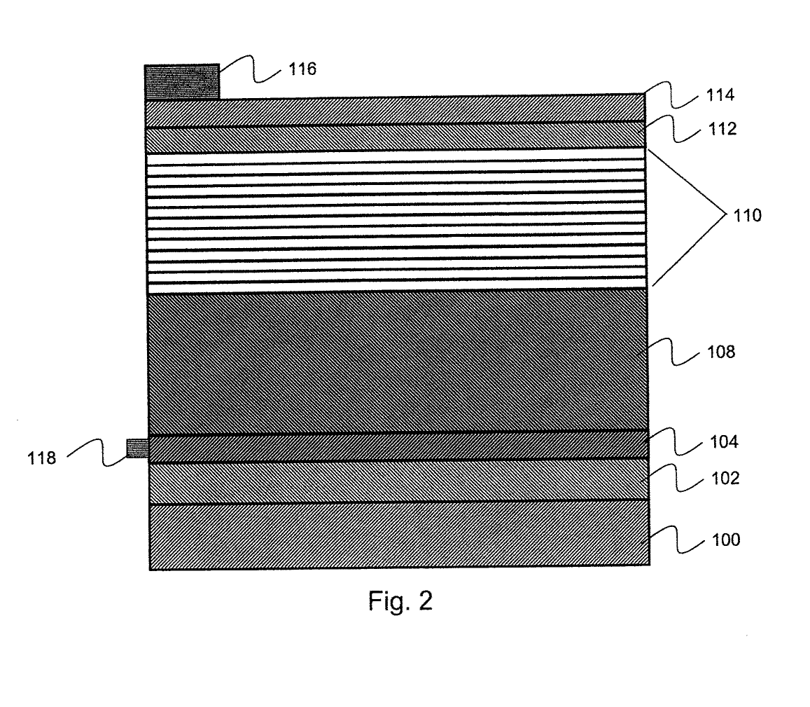

FIG. 2 shows a schematic view of an embodiment of a stack structure for a light emitting element in accordance with the current teachings. The layers in this embodiment include a substrate (Si) 100; a buffer layer (AlN) 102; a metal layer (ZrN, HfN, TiN or an alloy thereof) 104; a n-type layer (n-GaN:Si) 108; a multi-quantum well layer (InGaN—GaN) 110; a p-type layer (p-GaN:Mg) 112; a transparent layer (Au—Ni, ITO, ZnO) 114; a p-electrode (Au, Ag, Cu, Cr, W, Ni, Si, Al, Mo or alloy thereof) 116; and a n-electrode (Au, Ag, Cu, Cr, W, Ni, Si, Al, Mo or an alloy) 118. The buffer layer 102 can be grown by first depositing a thin layer of Al on Si and then heating of Al in the presence of N. Thin deposition of Al transforms to AlN in this heating process and provides a chemically stable receiving surface for further deposition of AlN. This step prevents formation of Si—N at elevated temperatures up to and beyond 1000° C. and readily seeds growth of AlN and subsequent layers. Although AlN can be deposited on Si at lower temperatures, compatibility with high temperature deposition processes can be desirable and cost effective. The AlN layer, while providing a high thermal conductivity interface, also provides electrical isolation between a ZrN metal layer 104 and the Si substrate 100, and provides a reaction barrier between the ZrN metal layer 104 and the Si substrate 100 during high temperature deposition of ZrN and subsequent growth of GaN.

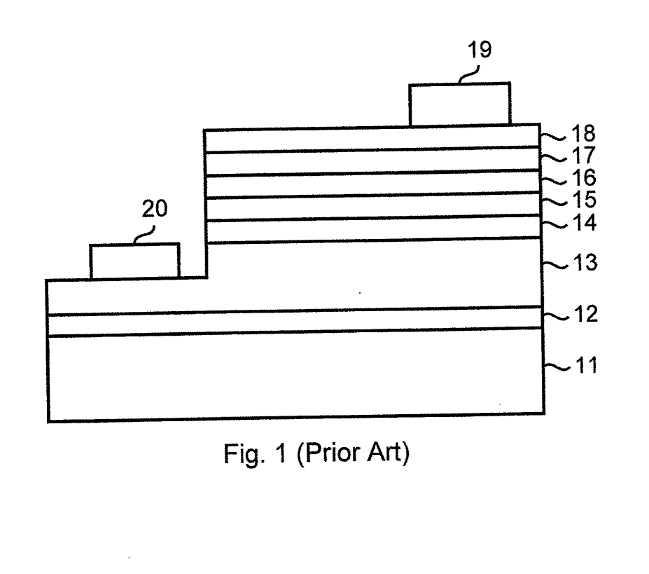

Since Si has poor light transmission qualities, light can be reflected more effectively using a back reflector metallic layer, such as the ZrN metal layer 104. To this end several candidates from the group of IVB nitrides consisting of ZrN, HfN, and TiN may be considered. ZrN provides a better lattice match for Si. The choice of GaN or InGaN for the multi-quantum well layer 110 is related to the type of LED that is sought. However, compatibility of the lattice structure with both types of layers is desired. The ZrN layer 104 provides reflectance and low light absorption to improve the light emitting qualities of the Si-based LED. The ZrN layer 104 also provides improved ohmic contact to GaN, thereby improving the electrical qualities of the two layers. In particular, the ohmic contact can be connected directly to the ZrN layer 104 as shown by reference numeral 118. This connectivity as shown in FIG. 2 advantageously provides a larger area for light to be emitted outward. See, e.g., FIG. 1 showing the prior art and the area taken up by the n-electrode 20. In accordance with light emission models, external quantum efficiency as a result of the aforementioned reflecting layer may increase by at least 26%.

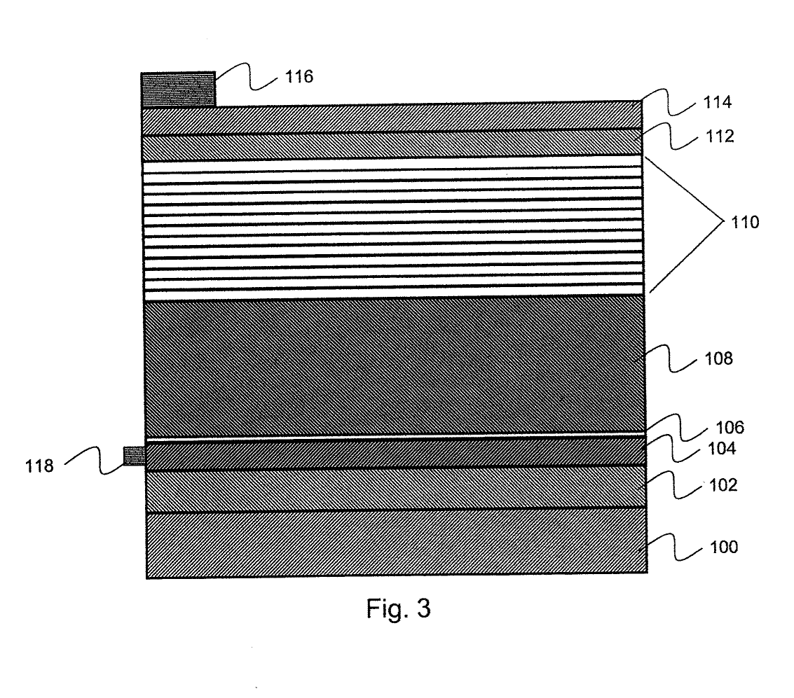

FIG. 3 shows another embodiment of a stack structure according to the current teachings. The difference between FIGS. 2 and 3 is an additional AlN layer 106. This additional AlN layer 106 provides a protective layer against oxidation of the metal layer 104, The preparation process, as will be further described below, up to the point of growing GaN is typically under vacuum conditions. In certain circumstances it may be necessary to “break” the vacuum and expose the metal layer 104 to air, thus undesirably increasing the chance of free-air oxidation. This can be the case if wafers are to be staged for long periods prior to growing GaN. The AlN layer 106 can be made sufficiently thin such that its lattice parameter conforms to the lattice parameter of a ZrN layer 104. The AlN layer 106 can also be made sufficiently thin to allow electrons to tunnel through it without appreciable resistance. The offset between the conduction bands of GaN and AlN reduces the effective potential barrier for electrons between GaN and ZrN.

ZrN(111)/AlN(0001)/Si(111) substrates were prepared by reactive dc magnetron sputtering (PVD Products Inc.). First, phosphorus-doped n-type Si(111) substrates (resistivity 1 mΩ-cm) were chemically oxidized in a Piranha solution (H₂O₂:H₂SO₄ ∥1:4) at room temperature for 20 minutes followed by a thorough rinse in de-ionized water to remove residual sulfur containing species. The oxide was then etched in a 40% ammonium fluoride (NH₄F) solution for 20 minutes, resulting in a stable, hydrogen-passivated silicon surface. Nitrogen was bubbled through the ammonium fluoride to further reduce dissolved oxygen so as to avoid the pitting of the silicon surface that is induced by dissolved oxygen. The substrates were subsequently rinsed in de-ionized water, blown dry with ultra pure nitrogen, and loaded into the sputter system loadlock. Due to the short hydrogen passivation lifetime in air at atmospheric pressure, the silicon substrates were loaded into the sputter system within two minutes of removal from the ammonium fluoride solution.

AlN and ZrN films were sputtered onto the Si(111) substrates from 99.95% Al and 99.95% Zr targets in an Ar/N₂ ambient with a throw distance of 13 cm. The base pressure of the system was less than 1×10⁻⁷ torr prior to deposition. Prior to all film depositions, the Al and Zr targets were presputtered for 5 minutes under deposition conditions. First, a thin layer of aluminum intended to protect the silicon surface from nitridation was deposited on the hydrogen-passivated silicon for 10 seconds at 25° C. in 3 mtorr Ar (Ar flow rate=10 sccm) with 100 W dc bias. The substrate temperature was then increased to 850° C. at 50° C./min in an Ar+N₂ gas mixture, which converted the thin protective Al film to AlN. AlN was then deposited at 850° C. in 3 mtorr Ar:N₂=10:3 with 50 W dc bias, followed by ZrN deposition at 850° C. in 8 mtorr Ar:N₂=10:8 with 80 W dc bias. The deposition rates of AlN and ZrN were 60 nm/hr and 80 nm/hr, respectively. Thickness ranges investigated were 80 nm to 450 nm for AlN and 70 nm to 300 nm for ZrN. A final capping layer of ˜3 nm of AlN was deposited for 90 sec in 3 mtorr Ar:N₂=10:3 at 100 W dc bias to protect the ZrN surface from oxidation. This thin AlN interface layer can also reduce the contact resistance of the ZrN contact to n-GaN by reducing the effective barrier height.

GaN films of varying thickness (200 nm to 2 μm) were subsequently deposited on the ZrN(111)/AlN(0001)/Si(111) substrates by OMVPE (Aixtron 200/4 HT) using a conventional two-step growth technique. First, a “low temperature” nucleation layer (˜15-50 nm) was deposited at 550° C., 200 mtorr total pressure, and a V/III ratio of ˜2800. The samples were then heated to 1020° C. at 100° C./min, which allowed for a post-growth anneal treatment of the GaN nucleation layer. Epitaxial GaN films were deposited at 1020° C., 100 mtorr, and a V/III ratio of ˜1200-2800 yielding a growth rate of 5-30 nm/min. Under these growth conditions, a transition from island growth to 2D planar growth was observed at a thickness of approximately 700 nm.

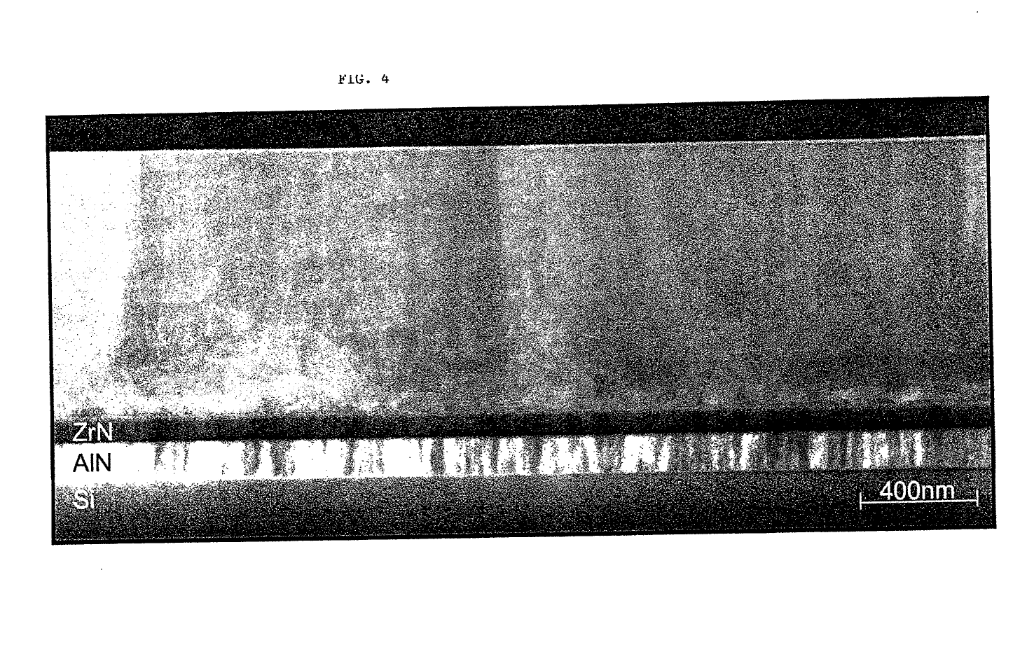

Epitaxial GaN(0001) on metallized Si(111) has been demonstrated with an epitaxial ZrN(111)/AlN(0001) intermediate bilayer (FIGS. 4-6). Direct deposition of ZrN on Si(111) substrates using the same growth conditions resulted in textured polycrystalline films with XRD patterns exhibiting 200, 111 and 220 reflections (not shown). The introduction of an intermediate epitaxial AlN buffer layer resulted in <111> oriented epitaxial ZrN under identical deposition conditions. Depending on ZrN or AlN layer thickness for epitaxial ZrN samples containing the AlN interlayer, the rocking curve FWHM values for the AlN 0002 reflection and the ZrN 111 reflection ranged from 1.2° to 1.8° and 0.9° to 1.9° respectively, whereas the rocking curve FWHM for the 111 ZrN reflection of the textured films of ZrN deposited directly on Si ranged from 2.2° to 15°.

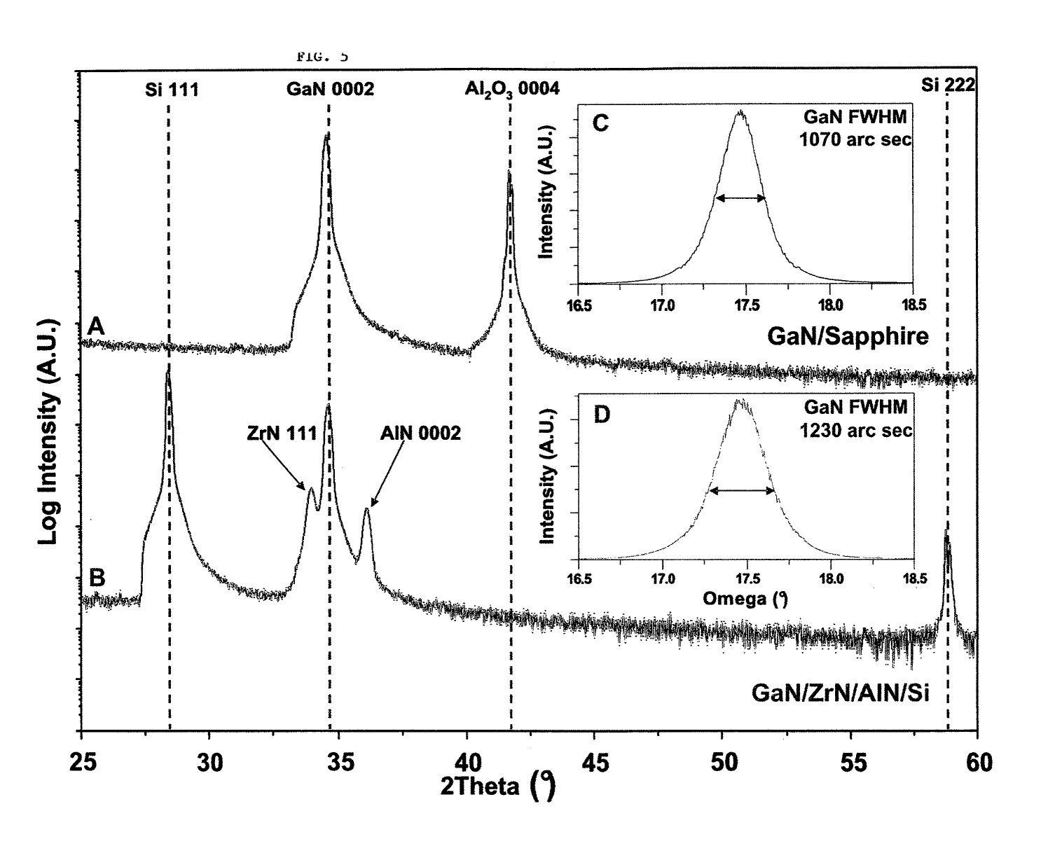

FIG. 4 shows a low magnification annular dark field STEM cross sectional image of a GaN/ZrN/AlN/Si(111) heterostructure, Rocking curve scans yielded 1430 arc sec (0.4°) for 860 nm of GaN, ˜1.28° for 80 nm ZrN, and ˜1.73° for 115 nm of AlN. FIG. 5 shows a XRD pattern from the same growth conditions of GaN by OVMPE on sapphire and ZrN/AlN/Si. Plot A shows a 2θ-θ scan for GaN grown on sapphire. Plot B shows a 2θ-θ scan for GaN grown on ZrN/AlN/Si thin film substrates. Plot C shows a Ω rocking curve for GaN deposited on sapphire. Plot D shows a Ω rocking curve for GaN deposited on ZrN/AlN/Si(111).

The GaN epitaxial film on AlN/ZrN/AlN/Si(111) imaged in FIG. 4 yielded a rocking curve FWHM for the 0002 GaN reflection of 1430 arc sec (0.4°), which is comparable to the 1230 arc sec measured for GaN grown on sapphire during the same growth run. Likewise, the GaN epitaxial films in FIG. 5 show 1230 arc sec and 1070 arc sec for sapphire and ZrN/AlN/Si substrates, respectively. Note that the rocking curve FWHM is continuously decreasing with each subsequent layer (e.g., 1.7° AlN; 1.3° ZrN; 0.4° GaN), suggesting that some of the extended defects that accommodate mosaicity are terminated in each layer or at each interface. In addition to high quality GaN growth, XRD and TEM indicated no observable reactions between the various layers, which can be attributed to the thermodynamic stability of AlN in contact with Si over a large temperature range. Without the AlN buffer layer, ZrN and Si can aggressively react to form zirconium silicide and silicon nitride. GaN films grown on ZrN/Si were found to be polycrystalline and diffraction peaks characteristic of Si₃N₄ and zirconium silicide were observed after GaN growth; diffraction peaks corresponding to ZrN were not present. Additionally, the GaN films appeared to be opaque and SEM images showed blisters as large as 20 μm in diameter.

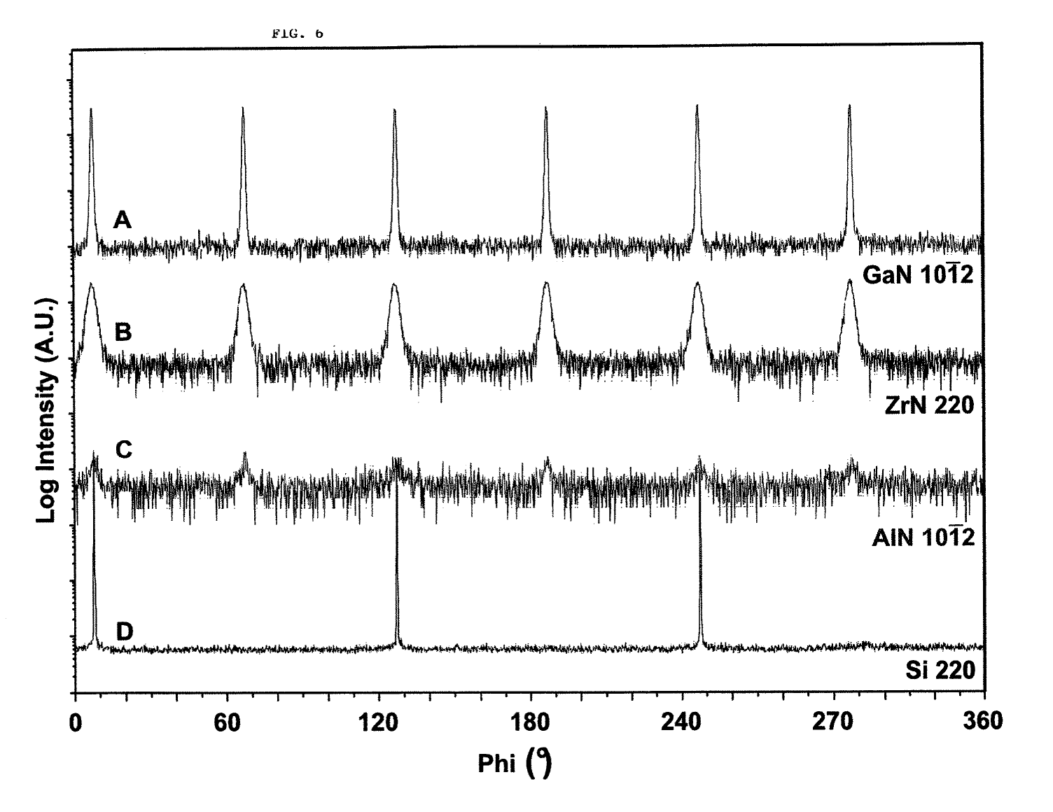

FIG. 6 shows asymmetric phi scans depicting the epitaxial relationships between the layers. Plot A is for a 1.5 μm GaN layer showing diffraction from the {10 1̅2} planes. Plot B is for a 230 nm ZrN layer showing diffraction from the {220} planes. Plot C is for a 115 nm AlN layer showing diffraction from the {10 1̅2} planes. Plot D is for a 450 μm Si(111) wafer showing diffraction from the {220} planes.

Asymmetric phi scans of a GaN/ZrN/AlN/Si heterostructure reveal the orientation relationships GaN(0001)[2 1̅1̅0]∥ZrN(111)[11 2̅]∥AlN(0001)[2 1̅1̅0]∥Si(111)[11 2̅] for the epitaxial layers. Note that the ZrN layer is bicrystalline with the two orientations related by a 180° rotation about the surface normal, as is expected when a crystalline phase with a 3-fold axis normal to the growth direction (ZrN) is grown on a template with 6-fold symmetry (AlN).

Epitaxial <0001>-oriented GaN films were deposited on ZrN(111)/AlN(0001)/Si(111) substrates using standard OMVPE growth conditions. These silicon-based substrates offer an alternative to sapphire and silicon carbide for (Al, In, Ga)N device fabrication using standard epitaxial growth techniques. The silicon offers better thermal conductivity and machinability while the ZrN film acts as an integral back contact and reflector. The intermediate AlN buffer layer serves as a thermally conductive diffusion barrier, permitting OMVPE growth of GaN at conventional growth temperatures (>1000° C.) without undesirable reactions with Si. The AlN also introduces an electrical isolation layer, thereby facilitating the design of integrated device arrays on the same die.

Although the results reported here do provide an avenue for cost reduction and scale-up of discrete LEDs and integrated LED arrays with a back reflector design, the ZrN/AlN intermediate layer stack does not by itself address the challenges posed by the difference in coefficient of thermal expansion between Si and GaN, which can result in cracking of the GaN when the layer thickness exceeds ˜1 μm. Furthermore, GaN grown on ZrN/AlN/Si generally contains a high threading dislocation density, typical of GaN on sapphire. The problems of cracking and threading dislocation reduction can be addressed separately.

While exemplary embodiments incorporating the principles of the present invention have been disclosed hereinabove, the present invention is not limited to the disclosed embodiments. Instead, this application is intended to cover any variations, uses, or adaptations of the invention using its general principles. Further, this application is intended to cover such departures from the present disclosure as come within known or customary practice in the art to which this invention pertains and which fall within the limits of the appended claims.

We claim:

1. A light emitting diode having a metallized silicon substrate, comprising:
a silicon base;
a buffer layer disposed on the silicon base;
a metal layer disposed on the buffer layer; and
light emitting layers disposed on the metal layer.

2. The light emitting diode of claim 1, wherein the buffer layer is composed of AlN.

3. The light emitting diode of claim 1, wherein the metal layer is composed of ZrN.

4. The light emitting diode of claim 1, wherein the light emitting layers comprise:
an n-type layer disposed on the metal layer;
a multiple quantum well structure disposed on the n-type layer;
a p-type layer disposed on the multiple quantum well structure; and
a transparent layer disposed on the p-type layer.

5. The light emitting diode of claim 4, further comprising a p-electrode disposed on the transparent layer.

6. The light emitting diode of claim 4, further comprising an n-electrode disposed on the metal layer.

7. The light emitting diode of claim 6, wherein the n-type layer is composed of GaN.

8. The light emitting diode of claim 6, wherein the multiple quantum well structure comprises GaN and InGaN layers.

9. The light emitting diode of claim 6, wherein the p-type layer is composed of GaN:Mg.

10. The light emitting diode of claim 6, wherein the transparent layer is chosen from the group consisting of Au—Ni, Indium Tin Oxide, and ZnO.

11. A light emitting diode having a metallized silicon substrate, comprising:
a silicon base;
a buffer layer disposed on the silicon base;
an metal layer disposed on the buffer layer;
an oxidation prevention layer disposed on the metal layer; and
light emitting layers disposed on the oxidation prevention layer.

12. The light emitting diode of claim 11, wherein the light emitting layers comprise:
an n-type layer disposed on the oxidation prevention layer;
a multiple quantum well structure disposed on the n-type layer;
a p-type layer disposed on the multiple quantum well structure;
a transparent layer disposed on the p-type layer;
a p-electrode disposed on the transparent layer; and
an n-electrode disposed on the metal layer.

13. The light emitting diode of claim 11, wherein the buffer layer is composed of AlN.

14. The light emitting diode of claim 13, wherein the metal layer is composed of ZrN.

15. The light emitting diode of claim 14, wherein the oxidation prevention layer is composed of AlN.

16. A method of forming a light emitting diode having a metallized silicon substrate, the method comprising:
preparing a silicon base surface;
depositing a thin layer of aluminum on the silicon base surface;
exposing the thin layer of aluminum on the silicon base surface to nitrogen gas to form an aluminum nitride base surface;
depositing additional aluminum on the aluminum nitride base surface in the presence of the nitrogen gas to form an aluminum nitride layer; and
depositing zirconium on the aluminum nitride layer in the presence of the nitrogen gas to form an zirconium nitride layer.

17. The method of claim 16, further comprising depositing gallium nitride film on the zirconium nitride layer using an organometallic vapor phase epitaxy process.

18. The method of claim 16, further comprising:
depositing a thin layer of aluminum in the presence of the nitrogen gas on the zirconium nitride layer to form a thin upper aluminum nitride layer.

19. The method of claim 18, wherein the thin upper aluminum nitride layer is about 3 nm in thickness.

20. The method of claim 18, further comprising depositing gallium nitride film on the thin upper aluminum nitride layer using an organometallic vapor phase epitaxy process.
